(19) United States
(12) Patent Application Publication
(10) Pub. No.: US 2026/0106606 A1
(43) Pub. Date: Apr. 16, 2026

(54) ADAPTIVE WINDOW COMPARATOR

(71) Applicant: TEXAS INSTRUMENTS INCORPORATED, Dallas, TX (US)

(72) Inventors: Joerg GOLLER, Zweikirchen (DE); Dominik GERL, Buch Am Erlbach (DE)

(21) Appl. No.: 18/915,175

(22) Filed: Oct. 14, 2024

(51) Int. Cl. H03K 5/14; H03K 5/24; H03K 5/00

(52) U.S. Cl. CPC H03K 5/14; H03K 5/249; H03K 2005/00202

(57) ABSTRACT

In some examples, a circuit includes a window comparator circuit. The window comparator circuit is configured to receive a input signal and a feedback signal, determine a delayed representation of the feedback signal based on a window control signal, determine, based on the feedback signal and the delayed representation of the feedback signal, a time window, responsive to a rising edge of the input signal occurring in the time window, or responsive to a falling edge of the input signal occurring in the time window, determine that the input signal and the feedback signal are locked, and responsive to the rising edge of the input signal occurring outside of the time window, or responsive to the falling edge of the input signal occurring outside of the time window, provide a pulse signal having an asserted value for a programmed period of time.

### BACKGROUND

A delay-locked loop (DLL) observes a periodic input signal or reference signal to create a feedback signal matching a certain delay. Based on that delay, the DLL determines a correction value to modify timing of the feedback signal to reduce or increase the delay.

### SUMMARY

In some examples, a circuit includes a window comparator circuit having first, second, and third input terminals, and first and second output terminals. The circuit also includes a counter having first and second input terminals and an output terminal, the first input terminal of the counter coupled to the first output terminal of the window comparator circuit, and the second input terminal of the counter coupled to the second output terminal of the window comparator circuit. The circuit also includes a current generator having an input terminal, a window control output terminal, and a plurality of delay output terminals, the input terminal of the current generator coupled to the output terminal of the counter, and the window control output terminal coupled to the third input terminal of the window comparator circuit. The circuit also includes a plurality of delay circuits coupled in series between the first input terminal of the window comparator circuit and the second input terminal of the window comparator circuit, each delay circuit having a delay control input terminal coupled to a respective one of the plurality of delay output terminals of the current generator.

In some examples, a circuit includes a window comparator circuit. The window comparator circuit is configured to receive a input signal and a feedback signal. The window comparator circuit is also configured to determine a delayed representation of the feedback signal based on a window control signal. The window comparator circuit is also configured to determine, based on the feedback signal and the delayed representation of the feedback signal, a time window. The window comparator circuit is also configured to, responsive to a rising edge of the input signal occurring in the time window, or responsive to a falling edge of the input signal occurring in the time window, determine that the input signal and the feedback signal are locked. The window comparator circuit is also configured to, responsive to the rising edge of the input signal occurring outside of the time window, or responsive to the falling edge of the input signal occurring outside of the time window, provide a pulse signal having an asserted value for a programmed period of time.

### BRIEF DESCRIPTION OF THE DRAWINGS

FIG. 1 is a block diagram of an example system.

FIG. 2 is a block diagram of an example DLL.

FIG. 3 is a block diagram of an example window comparator circuit.

FIG. 4 is a schematic diagram of an example delay circuit.

FIG. 5 is a schematic diagram of an example current generator.

FIG. 6 is a timing diagram of example waveforms.

FIG. 7 is a timing diagram of example waveforms.

FIG. 8 is a flowchart of an example method.

### DETAILED DESCRIPTION

As described above, a DLL observes a periodic input signal or reference signal to create a feedback signal matching a certain delay. Based on that delay, the DLL determines a correction value to modify timing of the feedback signal to reduce or increase the delay. Some existing approaches are binary in nature, decreasing a delay of the feedback signal in response to the feedback signal having a lagging phase in comparison to the input signal, and increasing a delay of the feedback signal in response to the feedback signal having a leading phase in comparison to the input signal. However, this can create challenges. For example, when the input signal and the feedback signal are near in value, such as having rising edges that are near each other temporally, the DLL, such as through the use of a phase frequency detection circuit, may repeatedly overshoot and undershoot the phase of the input signal with the phase of the feedback signal, creating jitter in the feedback signal.

Examples of this description provide for an adaptive window comparator. The adaptive window comparator includes a window into which the DLL attempts to lock the input signal. For example, rather than attempting to align rising edges of the input signal and the feedback signal, the DLL, via the adaptive window comparator, determines a feedback window. The feedback window may be a period of time between a rising edge of the feedback signal and a corresponding rising edge of a delayed representation of the feedback signal. The DLL shifts the feedback window forward or backward in time to cause a rising edge of the input signal to fall within the feedback window. Responsive to determining that the rising edge of the input signal occurs within the feedback window, the DLL determines that the feedback window is locked to the input signal. In some examples, the DLL may modify a width of the feedback window, such as to control a precision of a rising edge of the feedback signal with respect to a corresponding rising edge of the input signal for which the input signal will be deemed locked to the feedback window.

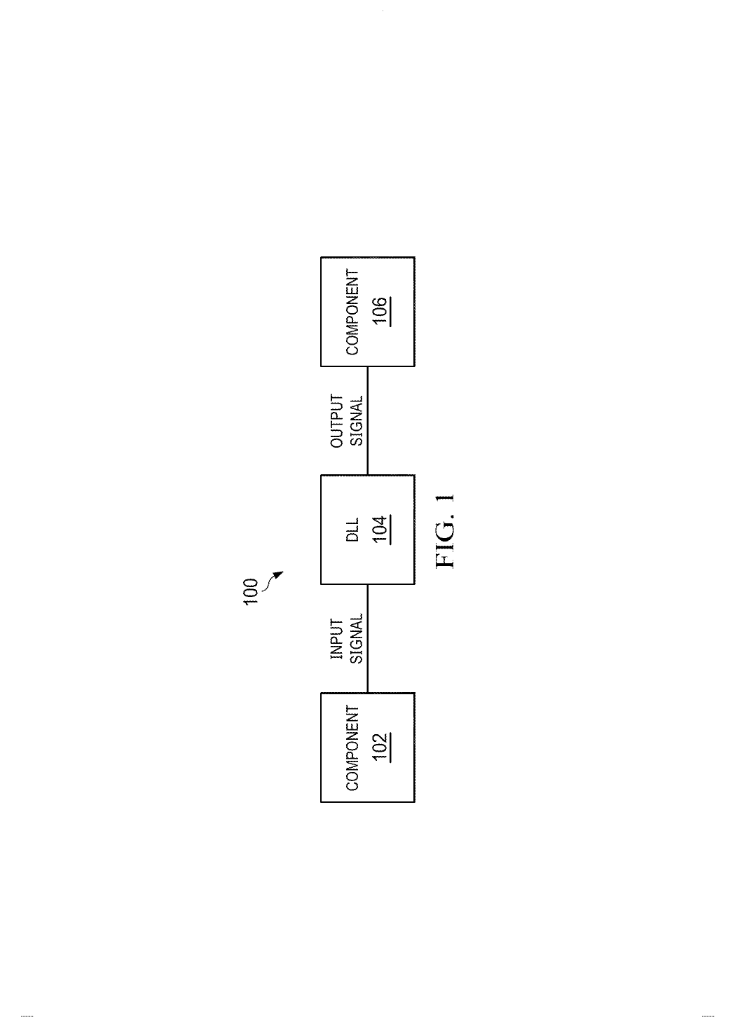

FIG. 1 is a block diagram of an example system 100. The system 100 may be any system or device in which a first component provides a clock signal that is retimed by a DLL and provided to a second component. For example, the system 100 may be suitable for performing clock and/or data recovery. In some examples, the system 100 includes a component 102, a DLL 104, and a component 106. In an example, the component 102 provides an input signal to the DLL 104. The component 102 may be any suitable component capable of providing an input signal, such as a clock signal, the scope of which is not limited herein. For example, the component 102 may be a controller, a processor, an oscillator, an analog clock generation circuit, or any other analog and/or digital component or components.

In an example, the DLL 104 receives the input signal and provides a feedback signal. In some examples, the DLL 104 may also provide one or more additional signals representative of different phases of the feedback signal. The DLL 104 may delay the input signal to form the feedback signal. For example, the DLL 104 may determine whether a rising edge of the input signal is within a time window or threshold variance of a corresponding rising edge of the feedback signal. Responsive to the rising edge of the input signal not being within the time windows of the corresponding rising edge of the feedback signal, the DLL 104 modifies a delay of the feedback signal. Responsive to the rising edge of the input signal being within the time window of the corresponding rising edge of the feedback signal, the DLL 104 determines that a lock exists between the feedback signal and the input signal. The DLL 104 provides the feedback signal as an output signal to the component 106. The component 106 may be any suitable component capable of receiving a signal, such as a clock signal, the output signal of the DLL 104, or the like, the scope of which is not limited herein. For example, the component 110602 may be a controller, a processor, an oscillator, an analog clock generation circuit, or any other analog and/or digital component or components. In some examples, the DLL 104 also provides one or more other signals to the component 106, the component 102, or any other suitable component, where the one or more other signals are representative of various phases of the feedback signal.

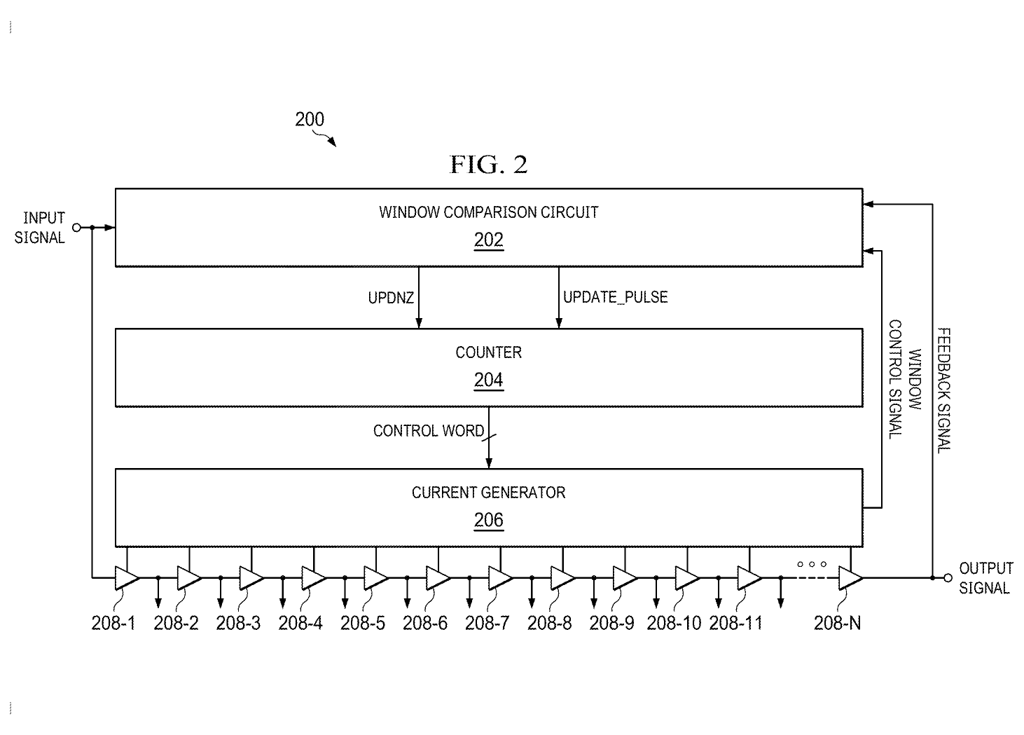

FIG. 2 is a block diagram of an example DLL 200. In an example, the DLL 200 is suitable for implementation in the system 100 as the DLL 104. In an example, the DLL 200 includes a window comparator circuit 202, a counter 204, a current generator 206, and delay circuits 208-1 ... 208-N. While described herein as a component of the system 100, in various examples the DLL 200 may be suitable for implementation in other systems. For example, the DLL 200 may be suitable for implementation in any system or device for which it is desirable to match a phase of a generated feedback signal to within a determined accuracy range of an input signal.

In an example, the window comparator circuit 202 has first, second, and third input terminals, and first and second output terminals. The window comparator circuit 202 receives the input signal at the first input terminal of the window comparator circuit 202, such as from the component 102. The window comparator circuit 202 is coupled at the second input terminal to an output terminal of the delay circuit 208-N. The third input terminal of the window comparator circuit 202 is coupled to a window control output terminal of the current generator 206. The window comparator circuit 202 also has first and second output terminals. The counter 204 has a first input terminal coupled to the first output terminal of the window comparator circuit 202 and has a second input terminal coupled to the second output terminal of the window comparator circuit 202. The counter 204 has an output terminal coupled to an input terminal of the current generator 206. In some examples, the coupling between the counter 204 and the current generator 206 is a single coupling over which multiple bits of digital data may be transmitted serially. In other examples, multiple couplings may exist between the counter 204 and the current generator 206 such that one respective bit of digital data may be provided via each of the multiple couplings. The current generator 206 includes a plurality of current output terminals, each of the output terminals respectively coupled to one of the delay circuits 208-N. For example, a first current output terminal of the current generator 206 is coupled to a current input of the delay circuit 208-1, a second current output terminal of the current generator 206 is coupled to a current input of the delay circuit 208-2, and a Nth current output terminal of the current generator 206 is coupled to a current input of the delay circuit 208-N. In the example of FIG. 2, 12 delay circuits 208 are shown. However, in other examples, any other suitable number of delay circuits may be used, such as 4, 8, or any other suitable number. In an example, an input terminal of the delay circuit 208-1 receives the input signal (e.g., is, or may be, coupled to the first input terminal of the window comparator circuit 202). An output of a respective delay circuit 208-X is coupled to an input terminal or a next subsequent delay circuit 208-(X+1), where X is a whole number and 0<X<N. Each output terminal of a respective delay circuit may also represent a different phase of the feedback signal provided at the output terminal of the delay circuit 208-N, where the feedback signal is an output signal of the DLL 200 that may be provided to another component, such as the component 106.

In an example of operation, the window comparator circuit 202 receives the input signal and the feedback signal. The window comparator circuit 202 generates a delayed representation of the feedback signal (e.g., a delayed feedback signal) based on a window control signal received from the current generator 206. Thus, the window comparator circuit 202 forms a window having a beginning aligned with a rising edge of the feedback signal and an ending aligned with a rising edge of the delayed feedback signal. Responsive to the input signal having a rising edge occurring prior to a rising edge of the feedback signal, the window comparator circuit 202 provides a signal (e.g., UPDNZ) at its first output terminal having a logical high value and provides a signal pulse (UPDATE_PULSE) at its second output terminal. Conversely, responsive to the input signal having a rising edge occurring after to a rising edge of the delayed feedback signal, the window comparator circuit 202 provides UPDNZ at its first output terminal having a logical low value and provides UPDATE_PULSE at its second output terminal. Finally, responsive to the input signal having a rising edge occurring in the window (e.g., following the rising edge of the feedback signal and prior to the rising edge of the delayed feedback signal), the window comparator circuit 202 no longer provides UPDATE_PULSE at the second output terminal of the window comparator circuit 202.

The counter 204 receives UPDNZ and UPDATE_PULSE and generates a control word based on UPDNZ and UPDATE_PULSE. In an example, the control word is a digital value having multiple bits. The counter 204 increments or decrements its count responsive to receipt of a rising edge in UPDATE_PULSE. For example, responsive to receipt of a rising edge in UPDATE_PULSE and UPDNZ having a logical high value, the counter 204 increments its count. Conversely, responsive to receipt of a rising edge in UPDATE_PULSE and UPDNZ having a logical low value, the counter 204 decrements its count. The counter 204 may be implemented according to any suitable hardware architecture, the scope of which is not limited herein. The counter 204 provides each respective bit of the control word to the current generator 206 to control a current provided by the current generator 206 to the delay circuits 208.

The current generator 206 receives the control word from the counter 204 and provides current signals to the delay circuits 208 based on a value of the control word. The current generator 206 also provides the window control signal to the window comparator circuit 202 having fractional value of the current signals provided to the delay circuits 208. In some examples, the current generator 206 has a binary weighted architecture. In such an architecture, the current generator 206 includes multiple current sources, and each current source is configured to provide a current having a value of 2^{m} of a bit used to control switching of that respective current source. In such an example, m is a bit position in the control word and the control word includes bits <8:0>. In other examples, the control word may have any suitable number of bits corresponding to a number of current sources of the current generator 206. As the control word increases in value, such as resulting from the input signal trailing the delayed feedback signal, a current provided by the current generator 206 to the delay circuits 208 decreases in value, increasing a delay provided by the delay circuits 208. Conversely, as the control word decreases in value, such as resulting from the input signal leading the feedback signal, the current provided by the current generator 206 to the delay circuits 208 increases in value, decreasing the delay provided by the delay circuits 208.

Each delay circuit 208 receives one respective current signal from the current generator 206 and implements a delay based on that received current signal. For example, as a value of a received current signal increases, an amount of delay provided by the delay circuit 208 decreases. Conversely, as the value of the received current signal decreases, the amount of delay provided by the delay circuit 208 increases. The delay circuit 208 may have any suitable architecture, the scope of which is not limited herein. In an example, a total delay provided by the DLL 200 from the input signal to the feedback signal is N*C_DLY*V_threshold/I_SUM, where C_DLY is a capacitance of each respective capacitor of the delay circuits 208, V_threshold is a threshold voltage of each respective delay circuit 208, as described further below, and I_SUM is a value of a current signal provided by the current generator 206 to each respective delay circuit 208.

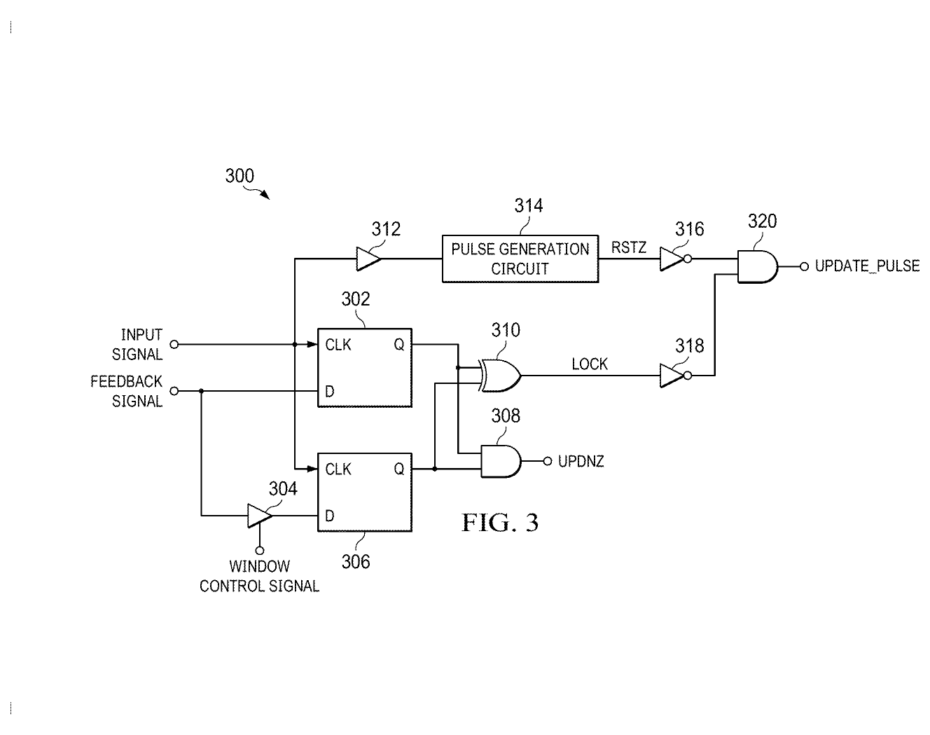

FIG. 3 is a block diagram of an example window comparator circuit 300. In at least some examples, the window comparator circuit 300 is suitable for implementation as the window comparator circuit 202, described above with respect to FIG. 2. In an example, the window comparator circuit 300 includes a first d-flip flop (DFF) 302, a first delay circuit 304, a second DFF 306, an AND logic circuit 308, an exclusive-OR (XOR) circuit 310, a second delay circuit 312, a pulse generation circuit 314, a first inverter circuit 316, a second inverter circuit 318, and an AND logic circuit 320.

In an example architecture of the window comparator circuit 300, the first DFF 302 has a clock input terminal at which the input signal is received, a data input terminal at which the feedback signal is provided, and a data output terminal. The first delay circuit 304 has a first input terminal coupled to the data input terminal of the first DFF 302, a second input terminal at which the window control signal is received, and has an output terminal. The second DFF 306 has a clock input terminal coupled to the clock input terminal of the first DFF 302, a data input terminal coupled to the output terminal of the first delay circuit 304, and has a data output terminal. The AND logic circuit 308 has a first input terminal coupled to the data output terminal of the first DFF 302, a second input terminal coupled to the data output terminal of the second DFF 306, and has an output terminal. The XOR logic circuit 310 has a first input terminal coupled to the data output terminal of the first DFF 302, a second input terminal coupled to the data output terminal of the second DFF 306, and has an output terminal. The second delay circuit 312 has an input terminal coupled to the clock input terminal of the first DFF 302, and has an output terminal. The pulse generation circuit 314 has an input terminal coupled to the output terminal of the second delay circuit 312, and has an output terminal. The first inverter circuit 316 has an input terminal coupled to the output terminal of the pulse generation circuit 314, and has an output terminal. The second inverter circuit 318 has an input terminal coupled to the output terminal of the XOR logic circuit 310, and has an output terminal. The AND logic circuit 320 has first input terminal coupled to the output terminal of the inverter circuit 316, a second input terminal coupled to the output terminal of the second inverter circuit 318, and has an output terminal. In an example, the window comparator circuit 300 provides UPDNZ at the output terminal of the AND logic circuit 308 and provides UPDATE_PULSE at the output terminal of the AND logic circuit 320.

In an example of operation of the window comparator circuit 300, the first DFF 302 receives the feedback signal and, responsive to receiving a rising edge in the input signal, latches a value of the feedback signal as provided at the data input terminal of the first DFF 302 to the output terminal of the first DFF 302. The first delay circuit 304 receives the feedback signal and generates or provides the delayed feedback signal. In an example, the amount of delay of a rising edge of the delayed feedback signal is determined at least partially based on a value of the window control signal. For example, as the window control signal increases in value, the amount of delay decreases, and vice versa. The second DFF 306 receives the delayed feedback signal and, responsive to receiving a rising edge in the input signal, latches a value of the delayed feedback signal as provided at the data input terminal of the second DFF 306 to the output terminal of the second DFF 306.

Responsive to both the first DFF 302 and the second DFF 306 providing logical high values at their respective data output terminals, the AND logic circuit 308 provides UPDNZ at its output terminal having a logical high value. Otherwise, the AND logic circuit 308 provides UPDNZ at its output terminal having a logical low value. Responsive to only one of the DFF 302 or the DFF 306 providing a logical high value at its respective data output terminal, the XOR logic circuit 310 provides a signal (e.g., LOCK) at the output terminal of the XOR logic circuit 310 having a logical high value. Otherwise, the XOR logic circuit 310 provides LOCK having a logical low value. In some examples, LOCK having a logical high value indicates that the input signal has a rising edge occurring within the window formed by the first DFF 302 and the second DFF 306. For example, based on the output signal of the first DFF 302 it is determined that the input signal has a rising edge occurring after a corresponding rising edge of the feedback signal, and based on the output signal of the second DFF 306 it is determined that the input signal has a rising edge occurring before a corresponding rising edge of the delayed feedback signal.

The second delay circuit 312 forms a delayed representation of the input signal and, responsive to the occurrence of a rising edge in the delayed representation of the input signal, the pulse generation circuit 314 provides a pulse signal (RSTZ). The first inverter 316 inverts RSTZ and the second inverter 318 inverts LOCK. Responsive to both RSTZ and LOCK having logical low values, the AND logic circuit 320 provides UPDATE_PULSE having a logical high value. Otherwise, the AND logic circuit 320 provides UPDATE_PULSE having a logical low value. As described above, in some examples, UPDATE_PULSE having a logical high value causes the counter 204 to increment or decrement a determined count based on the value of UPDNZ, modifying the control word provided to the current generator 206. This in turn modifies the window control signal and the feedback signal, moving the comparison window of the window comparator circuit 300.

In an example, a size or width of the comparison window may correspond to an accuracy of resulting phases of the feedback signal, as provided by the delay circuits 208, with respect to a phase of the received input signal. In some examples, a width of the comparison window may be approximately three times a minimum current step size of the current provided by the current generator 206. In other examples, the width of the comparison window may have any other suitable relation to the minimum current step size of the current provided by the current generator 206.

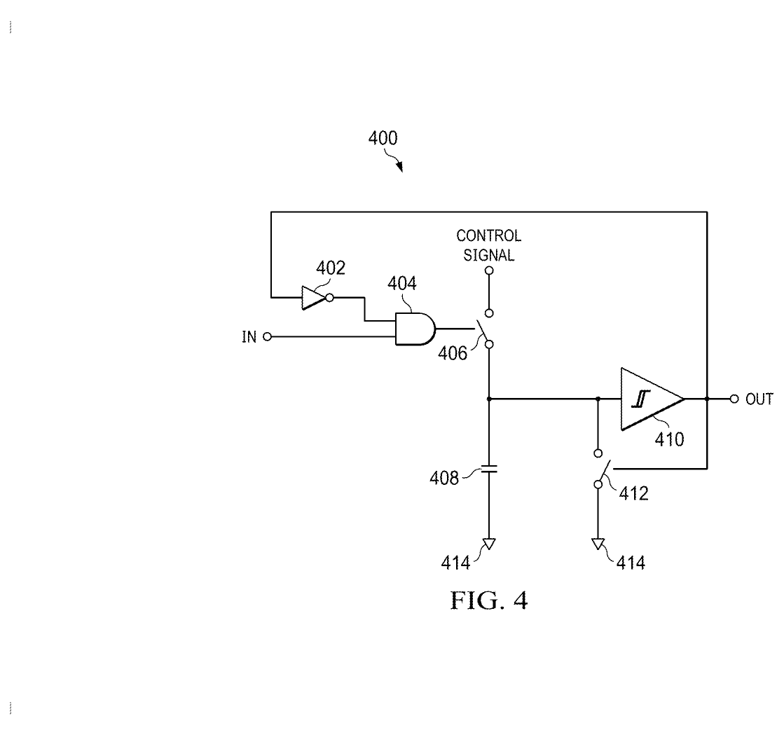

FIG. 4 is a schematic diagram of an example delay circuit 400. In at least some examples, the delay circuit 400 is suitable for implementation as the first delay circuit 304, described above with respect to FIG. 3. In at least some examples, the delay circuit 400 may also be suitable for implementation as any one or more of the delay circuits 208-1 to 208-N, described above with respect to FIG. 2. In an example, the delay circuit 400 includes an inverter circuit 402, an AND logic circuit 404, a switch 406, a capacitor 408, a Schmitt trigger 410, and a switch 412.

In an example architecture of the delay circuit 400, the inverter circuit 402 has an input terminal coupled to an output terminal of the Schmitt trigger 410, and has an output terminal. The AND logic circuit 404 has a first input terminal coupled to the output terminal of the inverter circuit 402, a second input terminal at which an input signal of the delay circuit 400 is received, and has an output terminal. The switch 406 has a control terminal coupled to the output terminal of the AND logic circuit 404, a first terminal at which a current signal is received, and has a second terminal. The capacitor 408 has a first terminal coupled to the second terminal of the switch 406 and has a second terminal coupled to a ground terminal 414 at which a ground voltage potential is provided. The Schmitt trigger 410 has an input terminal coupled to the second terminal of the switch 406, and has the output terminal of the Schmitt trigger 410. The switch 412 has a control terminal coupled to the output terminal of the Schmitt trigger 410, a first terminal coupled to the second terminal of the switch 406, and has a second terminal coupled to the ground terminal 414.

In some examples, a data input signal (e.g., a signal to be delayed) is received at the second input terminal of the AND logic circuit 404, a control signal for controlling an amount of delay of the delay cell 400 is received at the first terminal of the switch 406, and a data output signal (e.g., the delayed representation of the signal received at the second input terminal of the AND logic circuit 404) is provided at the output terminal of the Schmitt trigger 410.

In an example of operation of the delay circuit 400, responsive to receipt of the input signal having a logical high value and the delayed representation of the input signal having a logical low value, the AND logic circuit 404 provides a signal having a logical high value to cause the switch 406 to close. Responsive to the switch 406 closing, the capacitor 408 begins to charge. In some examples, a charging rate of the capacitor 408 is determined according to a value of current of the control signal received at the first terminal of the switch 406 – the greater the current, the faster the charging of the capacitor 408, and vice versa. As the capacitor 408 charges, a voltage provided by the capacitor 408 at the input terminal of the Schmitt trigger 410 increases. Responsive to the voltage provided by the capacitor 408 at the input terminal of the Schmitt trigger 410 exceeding a threshold voltage of the Schmitt trigger 410, the Schmitt trigger 410 provides a signal at its output terminal having a logical high value. The signal having the logical high value at the output terminal of the Schmitt trigger 410 causes the switch 412 to close, discharging the capacitor 408 to the ground terminal 414. As the capacitor 408 discharges, the voltage provided by the capacitor 408 at the input terminal of the Schmitt trigger 410 decreases. Responsive to the voltage provided by the capacitor 408 at the input terminal of the Schmitt trigger 410 decreasing to be below the threshold voltage of the Schmitt trigger 410, the Schmitt trigger 410 provides the signal at its output terminal having a logical low value. The logical low value of the signal causes the switch 412 to open and the delay circuit 400 is reset, awaiting a subsequent logical high value of the input signal received at the second input terminal of the AND logic circuit 404.

In the example of the delay circuit 400 implemented as the first delay circuit 304 of the window comparator circuit 300 of FIG. 3, the capacitor 408 may have a capacitance approximately equal to one-third of the capacitance of corresponding capacitors 408 of examples of the delay circuit 400 implemented as the delay circuits 208-1 through 208-N of the DLL 200 of FIG. 2.

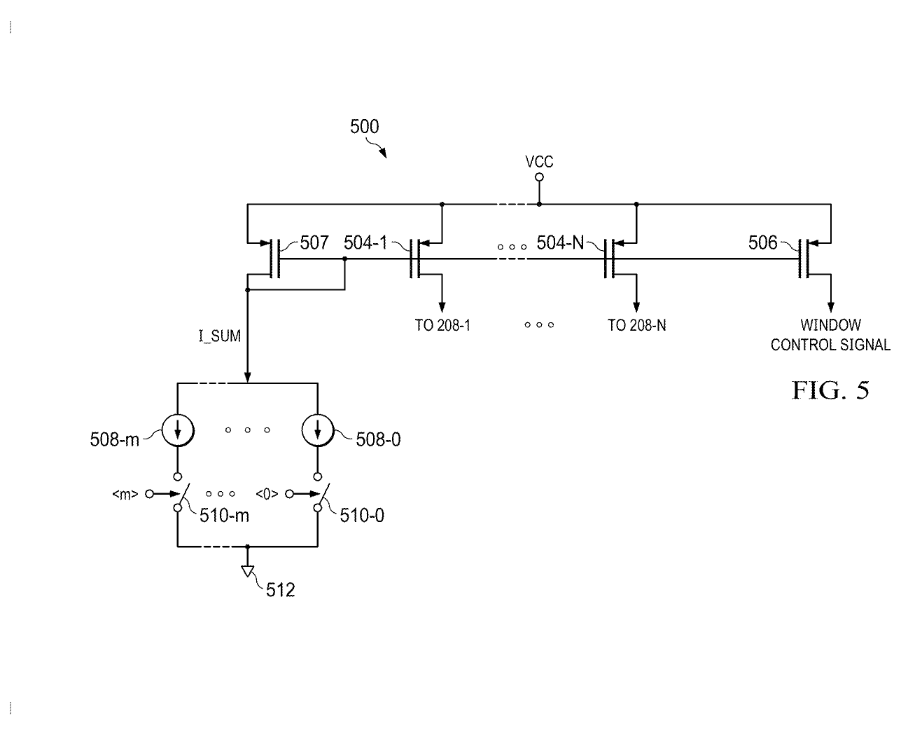

FIG. 5 is a schematic diagram of an example current generator 500. In at least some examples, the current generator 500 is suitable for implementation as the current generator 206, described above with respect to FIG. 2. In an example, the current generator includes a transistor 502, transistors 504-1, ... 504-N, a transistor 506, current sources 508-0, ... 504-m, and switches 510-0, ... 510-m.

In an example architecture of the current generator 500, the transistor 502 has a first terminal coupled to a voltage supply (VCC) terminal, a second terminal, and has a control terminal coupled to the second terminal of the transistor 502. The transistor 504-1 has a first terminal coupled to the VCC terminal, a second terminal coupled to the control terminal of the delay circuit 208-1, and a control terminal coupled to the control terminal of the transistor 502. The transistor 504-N has a first terminal coupled to the VCC terminal, a second terminal coupled to the control terminal of the delay circuit 208-N, and a control terminal coupled to the control terminal of the transistor 502. In this way, each transistor pair formed by the transistor 502 and a respective transistor 504 forms a current mirror such that a drain current of the transistor 502 is replicated to the respective transistor 504. Similarly, the transistor 506 has a first terminal coupled to the VCC terminal, a second terminal at which the window control signal is provided (e.g., such that the second control terminal is coupled to the control terminal of the first delay circuit 304), and a control terminal coupled to the control terminal of the transistor 502. As such, the transistors 502 and 506 form another current mirror. The current source 508-0 has a first terminal coupled to the second terminal of the transistor 502 and has a second terminal. The switch 510-0 has a first terminal coupled to the second terminal of the current source 508-0, a second terminal coupled to a ground terminal 512 at which a ground voltage potential is provided, and a control terminal coupled to the counter 204 and configured to receive bit <0> of the control word. The current source 508-m has a first terminal coupled to the second terminal of the transistor 502 and has a second terminal. The switch 510-m has a first terminal coupled to the second terminal of the current source 508-m, a second terminal coupled to the ground terminal 512, and a control terminal coupled to the counter 204 and configured to receive bit <m> of the control word.

In an example of operation of the current generator 500, responsive to a bit of the control word having a logical high value, a corresponding switch of the switches 510 closes. Responsive to a switch 510 closing, a current of a corresponding current source 508 is sunk from the VCC terminal through the transistor 502 to the ground terminal 512 and replicated to the transistors 504 and 506. The replicated currents are provided by the transistors 504 to corresponding delay circuits 208 to control an amount of delay of the delay circuits 208. The replicated current is also provided by the transistor 506 to the first delay circuit 304 to control a width of the comparison window formed by the window comparator circuit 300.

In some examples, the transistors 504 each have substantially a same width and length as the transistor 502. In examples of the current generator 500 implemented in a DLL 200 in which the capacitor of a first delay circuit 304 has one-third the capacitance as a delay circuit 208, the transistor 506 may have substantially similar characteristics (e.g., length and width ratio) as the transistors 504. Conversely, in examples of the current generator 500 implemented in a DLL 200 in which the capacitor of a delay circuit 304 has approximately the same capacitance as a delay circuit 208, the transistor 506 may be approximately one-third of the size of the transistors 504 (e.g., have a width to length ratio that is one-third that of the transistors 504). In other examples, the one-third ratio may be any other suitable value such that the window control signal has a value that is a scaled representation of I_SUM. In yet other examples, I_SUM may itself be used as the window control signal.

In an example, a step size (dT_step) of the current generator 500 is approximately equal to N*C_DLY*V_threshold*(1/(Z*iLSB*(Z+1)), where Z is a value of the control word and iLSB is the change of I_SUM at an increment or decrement of Z. Based on dT_step determined as shown above, an error (T_err) following assertion of LOCK (e.g., LOCK transitioning from a logical low value to a logical high value) is approximately equal to 2*dT_step. In an example, T_err is representative of an absolute value of error in time between the input signal and the feedback signal.

As described above, each output of a delay circuit 208 of the DLL 200 of FIG. 2 provides a respective phase of the feedback signal. For the example of FIG. 2 having 12 delay circuits, the phases are separate by approximately 30 degrees. The error in any given phase (P_err) is approximately equal to (T_err/T_period)*360, where T_period is approximately equal to N*C_DLY*V_threshold / (Z*iLSB). Thus, P_err becomes approximately equal to 720⁰/(Z+1) and percentage of P_err becomes approximately equal to 200/(N+1).

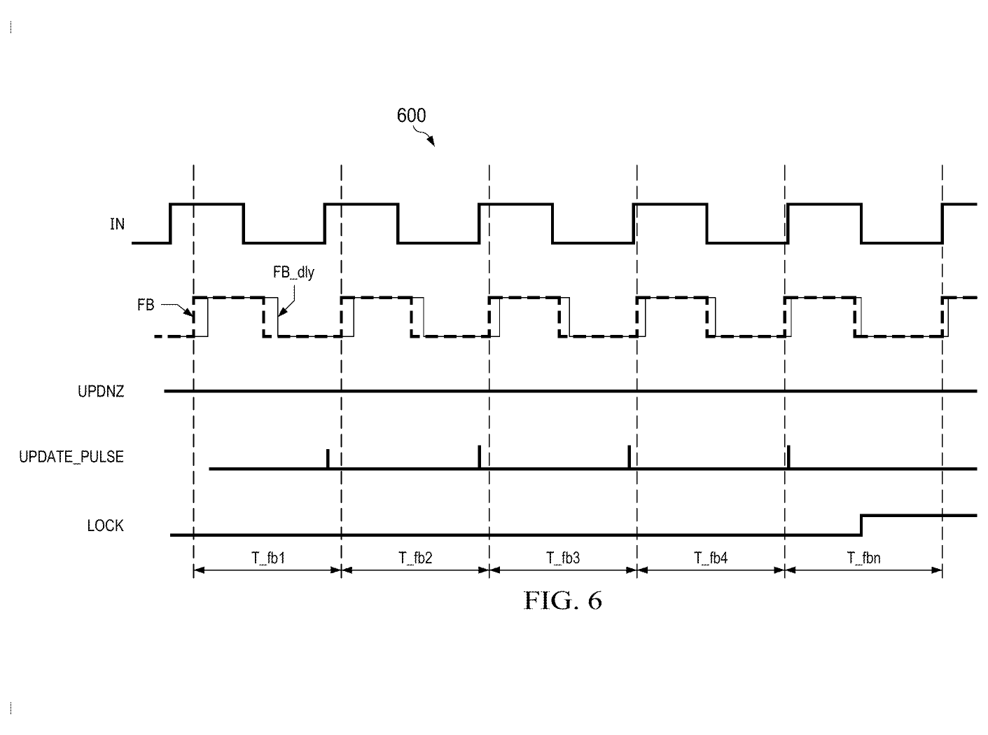

FIG. 6 is a timing diagram of example waveforms 600. In some examples, the waveforms 600 are representative of at least some signals that may be present in the DLL 200 of FIG. 2. Accordingly, reference may be made to components or signals of the DLL 200 in describing the waveforms 600. The waveforms 600 include the input signal (IN), the feedback signal (FB), the delay feedback signal (FB_dly), UPDNZ, UPDATE_PULSE, and LOCK. The waveforms 600 illustrate operation of the DLL 200 in which the delay of the DLL 200 (e.g., as implemented by the delay circuits 208) is too long and a rising edge of IN leads a rising edge of FB and is therefore outside of the comparison window.

As shown by the waveforms 600, a period of FB (T_fb1, ... T_fbn) and a width of the comparison window decreases through regulation of the delay time of the DLL 200. As further shown by the waveforms 600, responsive to receipt of a rising edge in IN while LOCK has a logical low value, a pulse is provided in the UPDATE_PULSE signal. Responsive to this pulse in the UPDATE_PULSE signal, the counter 204 decrements its determined count to cause the current generator 206 to increase a current provided to the delay circuits 208 and the window comparator circuit 202, decreasing the period of FB and the comparison window width. Responsive to the rising edge of IN occurring in the comparison window (e.g., following the rising edge of FB and preceding a corresponding edge of FB_dly), LOCK is provided having a logical high value and further pulses are not included in UPDATE_PULSE until IN changes to no longer have a rising edge occurring in the comparison window.

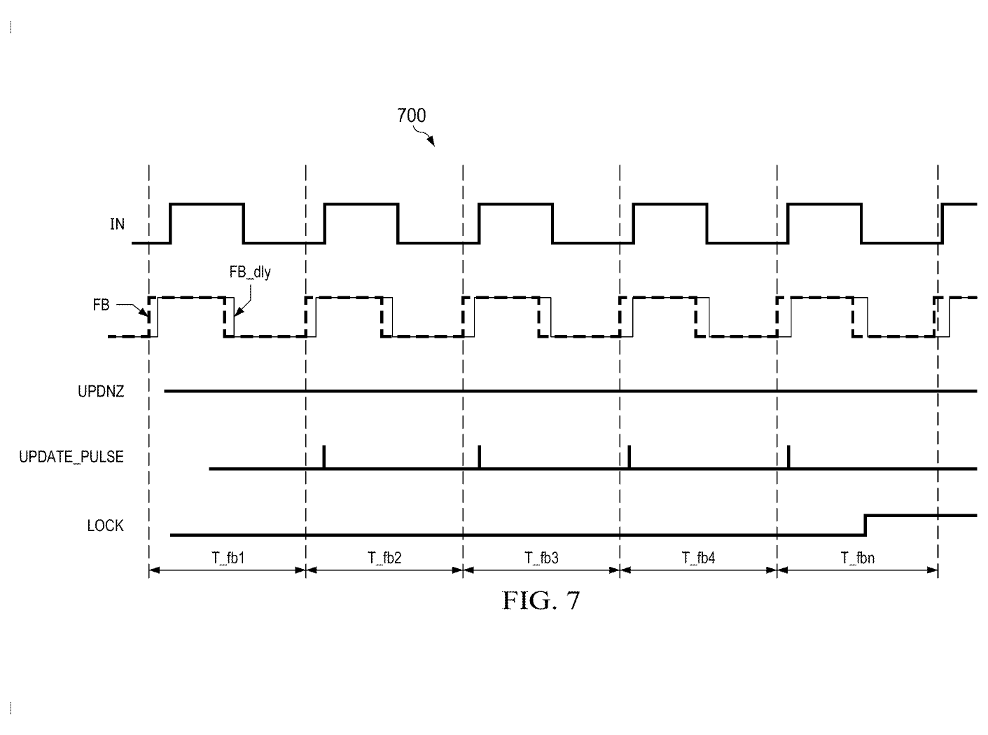

FIG. 7 is a timing diagram of example waveforms 700. In some examples, the waveforms 700 are representative of at least some signals that may be present in the DLL 200 of FIG. 2. Accordingly, reference may be made to components or signals of the DLL 200 in describing the waveforms 700. The waveforms 700 include the input signal (IN), the feedback signal (FB), the delay feedback signal (FB_dly), UPDNZ, UPDATE_PULSE, and LOCK. The waveforms 700 illustrate operation of the DLL 200 in which the delay of the DLL 200 (e.g., as implemented by the delay circuits 208) is too short and a rising edge of IN trails a rising edge of FB_dly and is therefore outside of the comparison window.

As shown by the waveforms 700, a period of FB (T_fb1, ... T_fbn) and a width of the comparison window increases through regulation of the delay time of the DLL 200. As further shown by the waveforms 700, responsive to receipt of a rising edge in IN while LOCK has a logical low value, a pulse is provided in the UPDATE_PULSE signal. Responsive to this pulse in the UPDATE_PULSE signal, the counter 204 increments its determined count to cause the current generator 206 to decrease a current provided to the delay circuits 208 and the window comparator circuit, increasing the period of FB and the comparison window width. Responsive to the rising edge of IN occurring in the comparison window (e.g., following the rising edge of FB and preceding a corresponding edge of FB_dly), LOCK is provided having a logical high value and further pulses are not included in the UPDATE_PULSE signal until IN changes to no longer have a rising edge occurring in the comparison window.

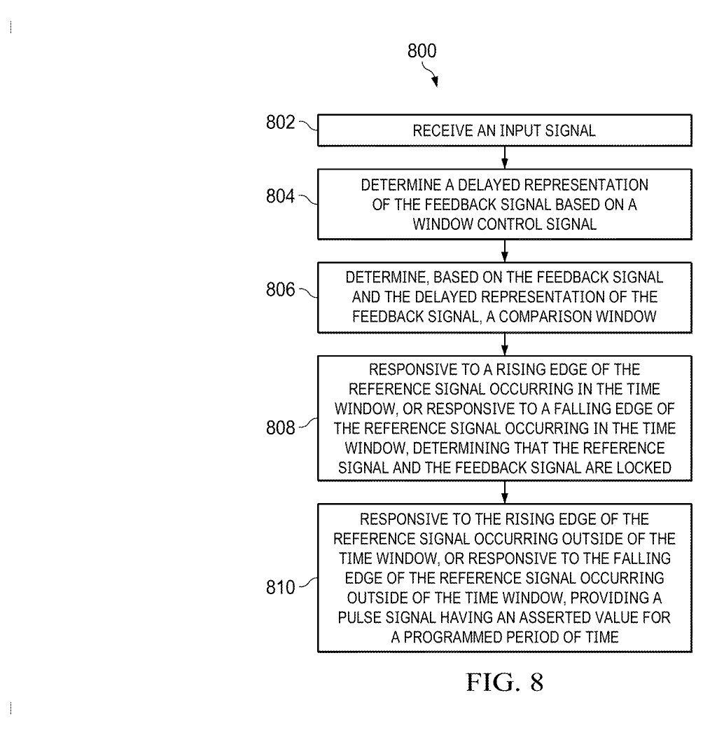

FIG. 8 is a flowchart of an example method 800. In some examples, the method 800 is a method of determining a lock of a feedback signal to an input signal. The method 800 may be implemented at least in part by the DLL 200 of FIG. 2. As such, reference may be made to components or signals of the DLL 200 in describing the method 800.

At operation 802, an input signal is received. In some examples, the input signal is a clock signal to which the DLL 200 determines a lock of a feedback signal (e.g., feedback clock signal) and/or provides multiple individual phase signals.

At operation 804, the DLL 200 determines a delayed representation of the feedback signal based on a window control signal. In some examples, the window control signal is provided by the current generator 206, as described above herein. The delayed representation of the feedback signal may be determined by a delay circuit, such as the delay circuit 304, also as described above herein.

At operation 806, the DLL 200 determines, based on the feedback signal and the delayed representation of the feedback signal, a comparison window (e.g., a time window). In some examples, the comparison window is determined by the window comparison circuit 300, as described above herein.

At operation 808, the DLL 200, responsive to a rising edge of the reference signal occurring in the time window, or responsive to a falling edge of the reference signal occurring in the time window, determining that the reference signal and the feedback signal are locked. In some examples, the determination of a lock is made by the window comparison circuit 300, as described above herein.

At operation 810, the DLL 200, responsive to the rising edge of the reference signal occurring outside of the time window, or responsive to the falling edge of the reference signal occurring outside of the time window, providing a pulse signal having an asserted value for a specified period of time. In some examples, the pulse signal is provided by the window comparison circuit 300, as described above herein.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. Furthermore, a voltage rail or more simply a “rail,” may also be referred to as a voltage terminal and may generally mean a common node or set of coupled nodes in a circuit at the same potential.

What is claimed is:

1. A circuit, comprising:
a window comparator circuit having first, second, and third input terminals, and first and second output terminals;
a counter having first and second input terminals and an output terminal, the first input terminal of the counter coupled to the first output terminal of the window comparator circuit, and the second input terminal of the counter coupled to the second output terminal of the window comparator circuit;
a current generator having an input terminal, a window control output terminal, and a plurality of delay output terminals, the input terminal of the current generator coupled to the output terminal of the counter, and the window control output terminal coupled to the third input terminal of the window comparator circuit; and
a plurality of delay circuits coupled in series between the first input terminal of the window comparator circuit and the second input terminal of the window comparator circuit, each delay circuit having a delay control input terminal coupled to a respective one of the plurality of delay output terminals of the current generator.

2. The circuit of claim 1, wherein the window comparator circuit comprises:
a first delay circuit having input and output terminals;
a first d-flip flop having a clock input terminal, a data input terminal, and an output terminal, the data input terminal of the first d-flip flop coupled to the input terminal of the first delay circuit;
a second d-flip flop having a clock input terminal, a data input terminal, and an output terminal, the clock input terminal of the second d-flip flop coupled to the clock input terminal of the first d-flip flop, and the data input terminal of the second d-flip flop coupled to the output terminal of the first delay circuit;
a second delay circuit having input and output terminals, the input terminal of the second delay circuit coupled to the clock input terminal of the first d-flip flop;
a pulse generator having input and output terminals, the input terminal of the pulse generator coupled to the output terminal of the second delay circuit;
a first logic circuit having first and second input terminals, and an output terminal, the first input terminal of the first logic circuit coupled to the output terminal of the first d-flip flop, and the second input terminal of the first logic circuit coupled to the output terminal of the second d-flip flop;
a second logic circuit having first and second input terminals, and an output terminal, the first input terminal of the second logic circuit coupled to the output terminal of the first d-flip flop, and the second input terminal of the second logic circuit coupled to the output terminal of the second d-flip flop, wherein the output terminal of the second logic circuit is coupled to the first output terminal of the window comparator circuit;
a first inverter circuit having input and output terminals, the input terminal of the first inverter circuit coupled to the output terminal of the pulse generator;
a second inverter circuit having input and output terminals, the input terminal of the second inverter circuit coupled to the output terminal of the first logic circuit; and
a third logic circuit having first and second input terminals, and an output terminal, the first input terminal of the third logic circuit coupled to the output terminal of the first inverter circuit, and the second input terminal of the third logic circuit coupled to the output terminal of the second inverter circuit, wherein the output terminal of the third logic circuit is coupled to the second output terminal of the window comparator circuit.

3. The circuit of claim 2, wherein the first logic circuit is an exclusive-OR logic circuit, the second logic circuit is an AND logic circuit, and the third logic circuit is an AND logic circuit.

4. The circuit of claim 2, wherein the first delay circuit comprises:
a third inverter circuit having input and output terminals;
a fourth logic circuit having first and second input terminals, and an output terminal, the first input terminal of the fourth logic circuit coupled to the output terminal of the third inverter circuit, and the second input terminal of the fourth logic circuit coupled to the data input terminal of the first d-flip flop;
a first switch having first and second terminals, and a control terminal, the first terminal of the first switch coupled to the third input terminal of the window comparator circuit, and the control terminal of the first switch coupled to the output terminal of the fourth logic circuit;
a capacitor having first and second terminals, the first terminal of the capacitor coupled to the second terminal of the first switch, and the second terminal of the capacitor coupled to a ground terminal;
a Schmitt trigger having input and output terminals, the input terminal of the Schmitt trigger coupled to the second terminal of the first switch, and the output terminal of the Schmitt trigger coupled to the input terminal of the third inverter circuit and to the data input terminal of the second d-flip flop; and
a second switch having first and second terminals, and a control terminal, the first terminal of the second switch coupled to the second terminal of the first switch, the control terminal of the second switch coupled to the output terminal of the Schmitt trigger, and the second terminal of the second switch coupled to the ground terminal.

5. The circuit of claim 4, wherein the fourth logic circuit is an AND logic circuit.

6. The circuit of claim 1, wherein the current generator comprises:
a plurality of current mirrors comprising a plurality of first transistors and a second transistor, each first transistor having a terminal coupled to a respective one of the plurality of delay output terminals, and the second transistor having a terminal coupled to the third input terminal of the window comparator circuit;
a plurality of current sources coupled in parallel to one of the first transistors; and
a plurality of switches, each switch coupled between a respective one of the plurality of current sources and a ground terminal and each having a control terminal coupled to a respective one of the plurality of delay output terminals of the current generator.

7. The circuit of claim 6, wherein the current sources are binary weighted.

8. The circuit of claim 1, wherein the output terminal of the counter comprises a multi-bit output, wherein the input terminal of the current generator comprises a multi-bit input, and wherein respective bit terminals of the counter and the current generator are coupled together.

9. A circuit, comprising:
a window comparator circuit configured to:
receive a input signal and a feedback signal;
determine a delayed representation of the feedback signal based on a window control signal;
determine, based on the feedback signal and the delayed representation of the feedback signal, a time window;
responsive to a rising edge of the input signal occurring in the time window, or responsive to a falling edge of the input signal occurring in the time window, determine that the input signal and the feedback signal are locked; and
responsive to the rising edge of the input signal occurring outside of the time window, or responsive to the falling edge of the input signal occurring outside of the time window, provide a pulse signal having an asserted value for a programmed period of time.

10. The circuit of claim 9, further comprising:
a counter configured to:
receive, from the window comparator circuit, the pulse signal and a up/down signal; and
responsive to the pulse signal having an asserted value, incrementing a count value responsive to the up/down signal having an asserted value and decrementing the count value responsive to the up/down signal having a de-asserted value;
a current generator configured to:
receive the count value from the counter;
control, responsive to the count value, a plurality of switches coupled to an array of binary weighted current sources to provide a plurality of delay control signals; and
provide the window control signal to the window comparator circuit; and
a delay circuit configured to:
receive the plurality of delay control signals; and
delay the input signal by an amount of time determined according to the plurality of delay control signals to form the feedback signal.

11. The circuit of claim 10, wherein the delay circuit is configured to, for each delay control signal, provide a respective phase signal of the input signal.

12. The circuit of claim 10, wherein the count value is a digital value comprising a plurality of bits, and wherein each bit of the count value controls a respective one of the plurality of switches.

13. The circuit of claim 10, wherein the window comparator circuit is configured to determine whether the input signal and the feedback signal are locked adaptively during runtime of the circuit in response to a changing delay of the input signal.

14. The circuit of claim 10, wherein:
the window comparator circuit has first, second, and third input terminals, and first and second output terminals;
the counter has first and second input terminals and an output terminal, the first input terminal of the counter coupled to the first output terminal of the window comparator circuit, and the second input terminal of the counter coupled to the second output terminal of the window comparator circuit;
the current generator has an input terminal, a window control output terminal, and a plurality of delay output terminals, the input terminal of the current generator coupled to the output terminal of the counter, and the window control output terminal coupled to the third input terminal of the window comparator circuit; and
the delay circuit comprises a plurality of delay circuits coupled in series between the first input terminal of the window comparator circuit and the second input terminal of the window comparator circuit, each delay circuit having a delay control input terminal coupled to a respective one of the plurality of delay output terminals of the current generator.

15. The circuit of claim 14, wherein the current generator comprises:
a plurality of current mirrors comprising a plurality of first transistors and a second transistor, each first transistor having a terminal coupled to a respective one of the plurality of delay output terminals, and the second transistor having a terminal coupled to the third input terminal of the window comparator circuit;
a plurality of current sources coupled in parallel to one of the first transistors; and
a plurality of switches, each switch coupled between a respective one of the plurality of current sources and a ground terminal and each having a control terminal coupled to a respective one of the plurality of delay output terminals of the current generator.

16. The circuit of claim 15, wherein the current sources are binary weighted.

17. The circuit of claim 14, wherein the window comparator circuit comprises:
a first delay circuit having input and output terminals;
a first d-flip flop having a clock input terminal, a data input terminal, and an output terminal, the data input terminal of the first d-flip flop coupled to the input terminal of the first delay circuit;
a second d-flip flop having a clock input terminal, a data input terminal, and an output terminal, the clock input terminal of the second d-flip flop coupled to the clock input terminal of the first d-flip flop, and the data input terminal of the second d-flip flop coupled to the output terminal of the first delay circuit;
a second delay circuit having input and output terminals, the input terminal of the second delay circuit coupled to the clock input terminal of the first d-flip flop;
a pulse generator having input and output terminals, the input terminal of the pulse generator coupled to the output terminal of the second delay circuit;
a first logic circuit having first and second input terminals, and an output terminal, the first input terminal of the first logic circuit coupled to the output terminal of the first d-flip flop, and the second input terminal of the first logic circuit coupled to the output terminal of the second d-flip flop;
a second logic circuit having first and second input terminals, and an output terminal, the first input terminal of the second logic circuit coupled to the output terminal of the first d-flip flop, and the second input terminal of the second logic circuit coupled to the output terminal of the second d-flip flop, wherein the output terminal of the second logic circuit is coupled to the first output terminal of the window comparator circuit;
a first inverter circuit having input and output terminals, the input terminal of the first inverter circuit coupled to the output terminal of the pulse generator;
a second inverter circuit having input and output terminals, the input terminal of the second inverter circuit coupled to the output terminal of the first logic circuit; and
a third logic circuit having first and second input terminals, and an output terminal, the first input terminal of the third logic circuit coupled to the output terminal of the first inverter circuit, and the second input terminal of the third logic circuit coupled to the output terminal of the second inverter circuit, wherein the output terminal of the third logic circuit is coupled to the second output terminal of the window comparator circuit.

18. The circuit of claim 17, wherein the first logic circuit is an exclusive-OR logic circuit, the second logic circuit is an AND logic circuit, and the third logic circuit is an AND logic circuit.

19. The circuit of claim 17, wherein the first delay circuit comprises:
a third inverter circuit having input and output terminals;
a fourth logic circuit having first and second input terminals, and an output terminal, the first input terminal of the fourth logic circuit coupled to the output terminal of the third inverter circuit, and the second input terminal of the fourth logic circuit coupled to the data input terminal of the first d-flip flop;
a first switch having first and second terminals, and a control terminal, the first terminal of the first switch coupled to the third input terminal of the window comparator circuit, and the control terminal of the first switch coupled to the output terminal of the fourth logic circuit;
a capacitor having first and second terminals, the first terminal of the capacitor coupled to the second terminal of the first switch, and the second terminal of the capacitor coupled to a ground terminal;
a Schmitt trigger having input and output terminals, the input terminal of the Schmitt trigger coupled to the second terminal of the first switch, and the output terminal of the Schmitt trigger coupled to the input terminal of the third inverter circuit and to the data input terminal of the second d-flip flop; and
a second switch having first and second terminals, and a control terminal, the first terminal of the second switch coupled to the second terminal of the first switch, the control terminal of the second switch coupled to the output terminal of the Schmitt trigger, and the second terminal of the second switch coupled to the ground terminal.

20. The circuit of claim 19, wherein the fourth logic circuit is an AND logic circuit.
